(19) United States
(12) Patent Application Publication
(10) Pub. No.: US 2005/0286440 A1
(43) Pub. Date: Dec. 29, 2005

(54) System and method for adaptive rate selection for wireless networks

(75) Inventors: Guenael T. Strutt, Sanford, FL (US); Sebnem Z. Ozer, Altamonte Springs, FL (US)

Correspondence Address: GARDNER CARTON & DOUGLAS LLP;(MESHNETWORKS/MOTOROLA) ATTN: PATENT DOCKET DEPT., 191 NORTH WACKER DRIVE, SUITE 3700, CHICAGO, IL, 60606-1698, US

(73) Assignee: MESHNETWORKS, INC., Maitland, FL (US)

(21) Appl. No.: 11/166,578

(22) Filed: Jun. 24, 2005

Related U.S. Application Data
(60) Provisional application No. 60/582,497, filed on Jun. 24, 2004.

(51) Int. Cl. G01R 31/08

(52) U.S. Cl. 370/253

(57) ABSTRACT

A system and method for dynamic rate adaptation in wireless networks is presented. A dynamic adjustment scheme adapts quickly to channel variation characteristics where adjustment values depend on the target data packet completion rates that maximizes the effective throughput. The required information is an estimate of the Medium Access Controller overhead including channel access delay. This a priori information can also be measured by the system a posteriori. Although the invention can be applied to both cellular and non-cellular systems, the exemplary embodiment is given for a carrier sense multiple access with collision avoidance (CSMA/CA) network.

This application claims the benefit of U.S. Provisional Application No. 60/582,497, filed Jun. 24, 2004, the entire content being incorporated herein by reference.

### BACKGROUND OF THE INVENTION

1. Field of the Invention

The present invention relates to a system and method for dynamic rate adaptation in wireless networks.

2. Description of the Related Art

Wireless communication networks, such as mobile wireless telephone networks, have become increasingly prevalent over the past decade. These wireless communications networks are commonly referred to as “cellular networks”, because the network infrastructure is arranged to divide the service area into a plurality of regions called “cells”. A terrestrial cellular network includes a plurality of interconnected base stations, or base nodes, that are distributed geographically at designated locations throughout the service area. Each base node includes one or more transceivers that are capable of transmitting and receiving electromagnetic signals, such as radio frequency (RF) communications signals, to and from mobile user nodes, such as wireless telephones, located within the coverage area. The communications signals include, for example, voice data that has been modulated according to a desired modulation technique and transmitted as data packets. As can be appreciated by one skilled in the art, network nodes transmit and receive data packet communications in a multiplexed format, such as time-division multiple access (TDMA) format, code-division multiple access (CDMA) format, or frequency-division multiple access (FDMA) format, which enables a single transceiver at a first node to communicate simultaneously with several other nodes in its coverage area.

In recent years, a type of mobile communications network known as an “ad-hoc” network has been developed. In this type of network, each mobile node is capable of operating as a base station or router for the other mobile nodes, thus eliminating the need for a fixed infrastructure of base stations. Details of an ad-hoc network are set forth in U.S. Pat. No. 5,943,322 to Mayor, the entire content of which is incorporated herein by reference.

More sophisticated ad-hoc networks are also being developed which, in addition to enabling mobile nodes to communicate with each other as in a conventional ad-hoc network, further enable the mobile nodes to access a fixed network and thus communicate with other mobile nodes, such as those on the public switched telephone network (PSTN), and on other networks such as the Internet. Details of these advanced types of ad-hoc networks are described in U.S. patent application Ser. No. 09/897,790 entitled “Ad Hoc Peer-to-Peer Mobile Radio Access System Interfaced to the PSTN and Cellular Networks”, filed on Jun. 29, 2001, in U.S. patent application Ser. No. 09/815,157 entitled “Time Division Protocol for an Ad-Hoc, Peer-to-Peer Radio Network Having Coordinating Channel Access to Shared Parallel Data Channels with Separate Reservation Channel”, filed on Mar. 22, 2001, and in U.S. patent application Ser. No. 09/815,164 entitled “Prioritized-Routing for an Ad-Hoc, Peer-to-Peer, Mobile Radio Access System”, filed on Mar. 22, 2001, the entire content of each being incorporated herein by reference.

Link adaptation schemes (for example, power and rate adoption) play an important role in increasing the performance of wireless systems. Most of the algorithms are based on some predetermined thresholds that depend on channel conditions without taking into account the effect of data rate selection on effective throughput. However, a need exists for a dynamic adjustment scheme that can adapt quickly to channel variation characteristics where adjustment values depend on the target packet completion rates that maximize the effective throughput.

### BRIEF DESCRIPTION OF THE DRAWINGS

These and other objects, advantages and novel features of the invention will be more readily appreciated from the following detailed description when read in conjunction with the accompanying drawings, in which:

FIG. 1 is a block diagram of an example ad-hoc wireless communications network including a plurality of nodes employing a system and method in accordance with an embodiment of the present invention;

FIG. 2 is a block diagram illustrating an example of a mobile node employed in the network shown in FIG. 1;

FIG. 3 is a block diagram illustrating the hardware abstraction mechanism for data rate selection.

FIG. 4 is a block diagram illustrating the data flow between the radio, the feedback mechanism, the rate selection algorithm and the overhead information.

FIG. 5 is a flow diagram illustrating the data rate selection process.

### DETAILED DESCRIPTION OF THE PREFERRED EMBODIMENTS

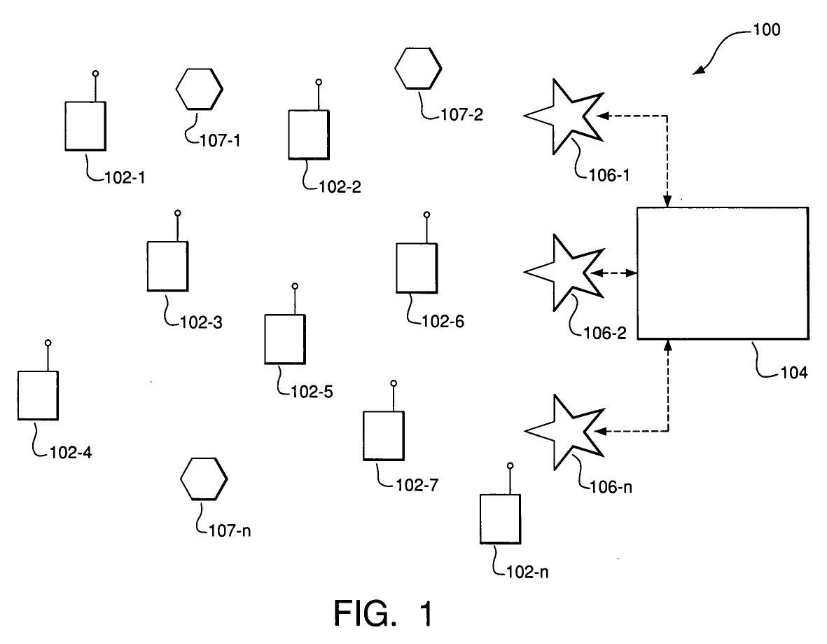

FIG. 1 is a block diagram illustrating an example of an ad-hoc packet-switched wireless communications network 100 employing an embodiment of the present invention. Specifically, the network 100 includes a plurality of mobile wireless user terminals 102-1 through 102-n (referred to generally as nodes 102 or mobile nodes 102), and can, but is not required to, include a fixed network 104 having a plurality of access points 106-1, 106-2, 106-n (referred to generally as nodes 106 or access points 106), for providing nodes 102 with access to the fixed network 104. The fixed network 104 can include, for example, a core local access network (LAN), and a plurality of servers and gateway routers to provide network nodes with access to other networks, such as other ad-hoc networks, the public switched telephone network (PSTN) and the Internet. The network 100 further can include a plurality of fixed routers 107-1 through 107-n (referred to generally as nodes 107 or fixed routers 107) for routing data packets between other nodes 102, 106 or 107. It is noted that for purposes of this discussion, the nodes discussed above can be collectively referred to as “nodes 102, 106 and 107”, or simply “nodes”.

As can be appreciated by one skilled in the art, the nodes 102, 106 and 107 are capable of communicating with each other directly, or via one or more other nodes 102, 106 or 107 operating as a router or routers for packets being sent between nodes, as described in U.S. Pat. No. 5,943,322 to Mayor, and in U.S. patent application Ser. Nos. 09/897,790, 09/815,157 and 09/815,164, referenced above.

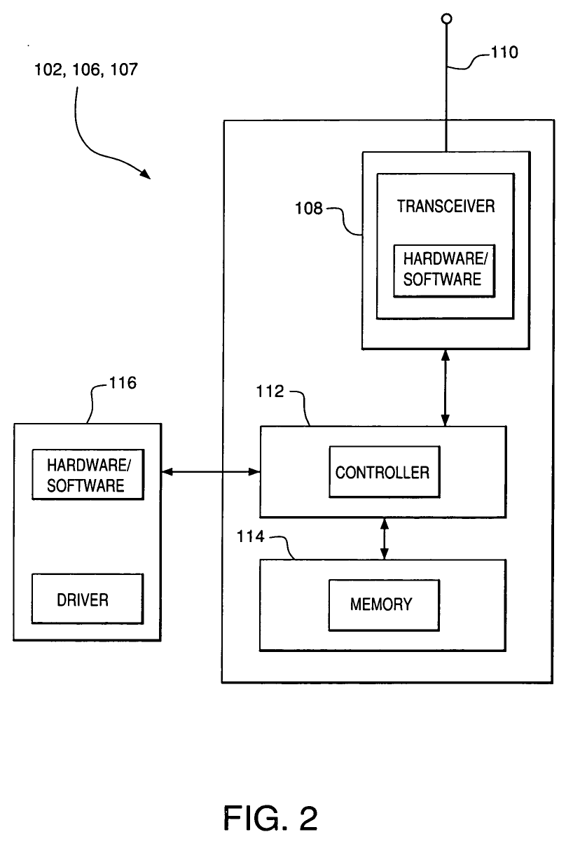

As shown in FIG. 2, each node 102, 106 and 107 includes a transceiver, or modem 108, which is coupled to an antenna 110 and is capable of receiving and transmitting signals, such as packetized signals, to and from the node 102, 106 or 107, under the control of a controller 112. The packetized data signals can include, for example, voice, data or multimedia information, and packetized control signals, including node update information.

Each node 102, 106 and 107 further includes a memory 114, such as a random access memory (RAM) that is capable of storing, among other things, routing information pertaining to itself and other nodes in the network 100. As further shown in FIG. 2, certain nodes, especially mobile nodes 102, can include a host 116 which may consist of any number of devices, such as a notebook computer terminal, mobile telephone unit, mobile data unit, or any other suitable device. Each node 102, 106 and 107 also includes the appropriate hardware and software to perform Internet Protocol (IP) and Address Resolution Protocol (ARP), the purposes of which can be readily appreciated by one skilled in the art. The appropriate hardware and software to perform transmission control protocol (TCP) and user datagram protocol (UDP) may also be included.

As mentioned briefly in the Background section above, link adaptation schemes (for example, power and rate adoption) play an important role in increasing the performance of wireless systems. For purposes of comparison, some of these schemes will now be briefly discussed. All of the documents cited herein are incorporated by reference herein.

In U.S. patent application No. 20030123406, a dynamic downlink data rate adaptation is proposed for High Data Rate technology such as 1xEV-DO standards for cellular networks. The basic idea is to enable mobile access terminal to estimate periodically the signal-to-interference-plus-noise ratio (SINR) and map it to a DRC (data rate control) rate option that maximizes the downlink rate while maintaining the requisite PER (packet error rate) in a fading channel environment. The mobile terminal delivers channel state information to the base station utilizing an uplink DRC channel. Each data rate in the DRC table is associated with a particular SINR required to achieve the same PER. Upon a successful transmission, the SINR threshold for the currently selected DRC set is decremented by a local factor of PER. Furthermore, all DRC set SINR values are also decremented by a global factor of PER. Upon a packet decoding failure, the SINR threshold for the currently selected DRC set is increased by a local factor while all DRC set SINR values are also increased by a global factor.

In U.S. patent application No. 20030083088, a decentralized joint power and rate adaptation technique is proposed for cellular systems such as EDGE, WCDMA and HDR. An exemplary embodiment is described for a WCDMA type system where time is divided into time slots which are grouped into a frame. Power control is performed on a slot-by-slot basis while data rate is modified on a per frame basis. The measured SINR is compared to a target SINR in order to increase or decrease the power level by a predetermined amount. At the end of each frame, the average SINR value of the previous frame is used to increase or decrease a rate adaptation counter. By comparing this counter to predetermined thresholds, the data rate is decreased or increased by ensuring that the rate is smaller than the maximum allowable rate. If transmission to the mobile station should be delayed, the rate is set to zero.

U.S. patent application No. 20020159395 proposes a technique to dynamically select data rates based upon observed channel conditions. An exemplary embodiment is presented for a cellular CDMA system. The mobile station estimates the path loss from the difference between Effective Radiated Power information carried from the base station and the received power level of the message sent from the base station. This information along with the transmit power level of the local transmit power amplifier is then distributed to the base station. The base station then computes the excessive power available at the mobile unit in order to select appropriate data rate. Specifically, the base station computes the required energy per symbol to total noise density (corresponding to a bit error rate (BER) value) for the user for each possible data rate by using the measured RMS delay spread that is a measurement of the relative strength of the multipath present on the reverse link from the maintenance channels. This may be computed offline. Using computed required energy per symbol to total noise, the received power required for each data rate is determined. From the path loss distributed by the mobile station, the transmit power required in the mobile unit is computed. The highest code rate that can support this power with some margin is then selected. The power level and data rate information is then sent to the mobile unit.

U.S. Pat. No. 6,539,205 proposes a system to monitor the quality of a traffic channel in order to modify transmission coding and/or data transmission rates. For systems where the control channel signal quality is representative of the traffic channel quality (e.g. GSM), the system estimates the BER of the control channel by comparing the received bits with the re-encoded bits. This information is then used to select appropriate coding scheme for the traffic channel. Channel quality estimation is based on the control channel since control channel transmissions are robust, hence providing robust error detection and correction. The system may be applied to both base stations and mobile stations and each station may exchange BER information.

The references given above are for cellular networks with characteristics different than the ad-hoc and mesh networks. The methods cited above rely on the base station's capabilities (e.g. measuring SNR). In U.S. Pat. No. 5,706,428, an automatic rate selection algorithm is proposed for IEEE 802.11 type networks. The invention includes the steps of transmitting the initial portion of the data at a predetermined rate, including in the initial portion a data rate identification segment and a length segment for the duration of the data portion. The MAC maintains a table containing neighbors'information. For each station identifier, successful receptions, transmissions and unsuccessful transmissions are counted for the applied data rate. A format for ACK messages is proposed to carry a preferred data rate derived in a receiving station, dependent on receive quality condition and a SNR value with respect to a message received from a transmitting station. At the transmitter, if the preferred data rate from the receiver is used, this value is compared to current data rate and is increased accordingly. Otherwise, the counter for consecutive correct Acks is increased. If this counter is greater than some predetermined threshold and if the SNR is OK then, the data rate is increased. SNR is computed as the ratio of received signal strength during the reception of the ACK message to the average silence level during periods at which no carrier signal is being received. If a positive acknowledgement is not received, the data rate is decreased. (see also “WaveLAN II: A High-Performance Wireless LAN for the Unlicensed Band”, by Kamerman and Monteban, Bell Labs Technical Journal, summer 1997: described as “Automatic Rate Fallback”). The drawback of such an algorithm is the stability as the rate is decreased with a single failure.

In U.S. patent application No. 20030152058 a method for adaptive fragmentation is proposed for multi-rate IEEE 802.11 networks. The authors compute the “effective throughput” for a given packet length by considering only the successful transmission of a packet. Retransmissions due to data failures are computed as a separate function to take into account the extra delay (though it is simply the number of retransmissions). Hence, link adaptation is performed by considering two different objective functions. However, these two objective functions are in fact dependent on one another. The embodiment of the present invention considers a single effective throughput computation that includes both successful and unsuccessful transmission times to compute the overall message delay. Furthermore, the objective function described in the present invention takes into account the waiting time between retransmissions, which depends on the MAC protocol. Another unique feature of the present invention is that the adaptation scheme uses the target packet completion rates computed from the effective throughput results as opposed to static thresholds used in U.S. patent application No. 20030152058.

In an article entitled “A Rate Adaptive MAC Protocol for Multihop Wireless Networks,” by G. Holland, N.Vaidya and P. Bahl in Mobicom 2001, a rate adaptive MAC protocol called the received based autorate is proposed for multihop wireless networks. The channel quality estimation and rate adaptation are done at the receiver site during RTS/CTS exchange just prior to packet transmission. The channel quality estimation is done from the signal strength of the RTS message. Each data rate is associated with a SNR threshold for a desired BER value. The highest rate that can support the required BER for the measured SNR is selected by the receiver. Since the duration in CTS may be different then RTS, final reservation of channel is done according to the duration field in a special subheader in the MAC header of the data packet. Note that control channel quality can be different than the data channel quality. Furthermore, this method would increase the delay of RTS/CTS exchange.

In an article entitled “Effective Throughput Analysis and Link Adaptation for IEEE 802.11a Wireless LANs,” by D. Qiao, S. Choi and K. G. Shin in IEEE Transactions on Mobile Computing, Vol 1, No 4, October-December 2002, the authors compute the effective throughput of 802.11a networks as the ratio of the expected delivered data payload to the expected transmission time. The transmission time includes MAC/PHY overheads, the backoff delay, the interframe intervals, ack transmission time and the potential frame retransmission times. The authors propose a rate adaptation scheme based on the effective throughput analysis by using a lookup table that consists of the data payload length, the wireless channel condition and the frame retry count. First, the authors present a MSDU based link adaptation scheme where every transmission attempt for a frame is assigned the same data rate. Since, wireless channel conditions can change between retransmission attempts this method can't adapt quickly to the channel variations. The second approach is MPDU based link adaptation where a data rate is selected for every retransmission attempt. For this purpose, an estimated channel variance between transmissions attempts is used. The computation does not include RTS/CTS overhead and the waiting time due to carrier sense multiple access with collision avoidance (CSMA/CA) type multiple access. Furthermore, the selection depends on the complex tables with different wireless channel conditions. However, the tables do not reflect the delay due to the channel contention.

In the proposed scheme in “Link Adaptation Strategy for IEEE 802.11 WLAN via Received Signal Strength Measurement,” by J. Pavon and S. Choi,in IEEE ICC 2003 the mobile station adapts the transmission rate based on the moving average of the received signal strength of the frames (e.g. ACK frames and beacons) sent from the AP. A minimum RSS threshold is maintained for each rate and three packet length range. The thresholds are updated according to the transmission status, for example, increased for successful transmissions and decreased otherwise. A lower rate is chosen if the packet exceeds the maximum number of transmission attempts. The throughput analysis is used only for the comparative evaluation of the proposal; it is not used for actual rate selection.

Unlike these techniques, the embodiments of the present invention described herein use a dynamic adjustment scheme that can adapt quickly to channel variation characteristics where adjustment values depend on the target packet completion rates that maximize the effective throughput. The required a priori information is a coarse estimate of the MAC overhead including channel access delay estimation, which is crucial for the systems where users do not have dedicated channels. This information can also be measured by the system.

Although the present invention can be applied to both cellular and non-cellular systems, the exemplary embodiment is given for CSMA/CA type networks. The exemplary embodiments also employ the computation of physical (PHY) mode tables with complete information about possible signal-to-noise (SNR) values and channel variation distribution between transmission attempts.

The data rate selection method is effectively used in conjunction with a hardware abstraction and normalization layer. This layer ensures that all network-layer features remain fully functional regardless of the type of physical and medium-access-control layers utilized.

The first step in ensuring that the link adaptation algorithm is independent of lower-layer specificities is to abstract the overhead information. The overhead information is compiled using total transmission time (for each data rate and quantized packet size) and extra transmission delays in case of transmission failure (for each data rate and quantized packet size). This overhead is translated into maximum effective throughput values, which are in turn translated into adjustment parameters (this procedure is explained in more detail below). These adjustment parameters are MAC/physical layer dependent, but they are abstracted in such a way that their effect on the data rate selection algorithm is consistent (i.e. if two MAC/physical layers provide a throughput of 500 Kbps for specific data rates and packet sizes, their adjustments values will be identical, even though the actual data rates and packet sizes are different).

The second step in ensuring that the algorithm is independent of lower-layer specificities is to normalize the feedback information. This is performed by translating the signal strength information into standardized values. Although any standard may be used, and would be equally successful if it is used consistently, a logarithmic scale of received power levels is the most widely used method. Also, MAC-specific events have to be normalized to particular events: successful and unsuccessful data packet transmissions have to be accounted for independently. Non-data packet transmissions (successful or not) should not be accounted for since data rate selection does not apply to them. For example, in CSMA/CA medium access control scenarios, control channel packets (RTS and CTS) are typically broadcast at a predefined data rate.

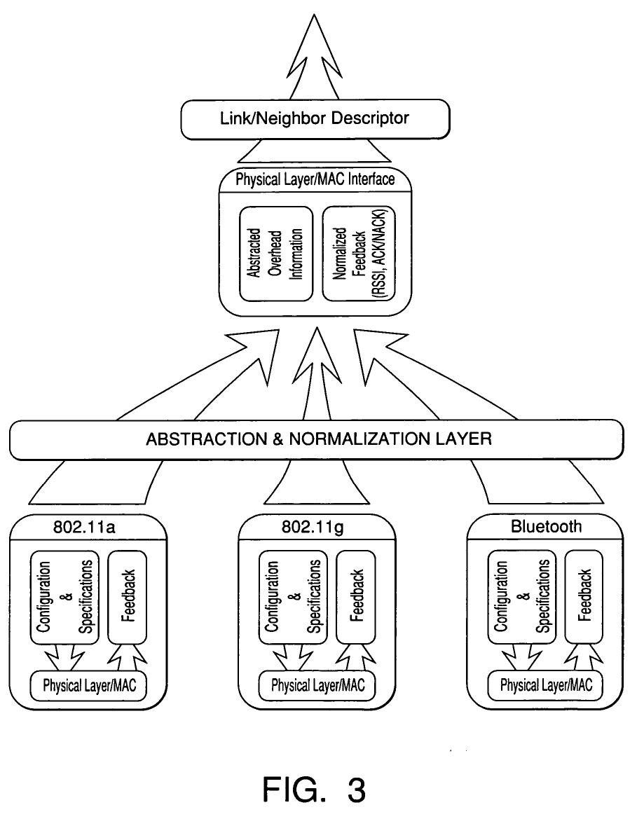

FIG. 3 is a diagram that shows the functionality of the hardware abstraction and normalization layer. Each exemplified physical layer (802.11 standards, Bluetooth etc.) has specificities (length of RTSs, data rates, packet failure penalty etc.), configurations (no RTS sent for small packets etc.) and feedback (number of retries, received signal strength etc). All those parameters are translated into information that can be interpreted by the link adaptation module.

The method of the present invention takes the packet size into account when determining the data rate. If the medium-access-controller performs packet fragmentation, the fragment size is used for data rate determination.

One of the advantages of the present invention is time independence. If the upper layers (network layer, or more specifically the layer that determines the data rate) are physically distinguishable from the MAC/PHY layers (for example, if the upper layers are running in a driver within the operating system of a host computer and the MAC/PHY layers are running in a peripheral device such as a PC card), then there will be a delay between the time the data rate is selected and feedback is provided. This will not cause convergence problems if the feedback contains the parameters that were initially provided to the physical layers at transmission. This can be performed by returning the original selected data rate with the necessary feedback (RSSI and ACK/NACK) within a comprehensive transaction summary report. In cases where the delay is considerable, the implementer may forego updating the data rate selection parameters if, for example, the current parameters have been updated in such a way that another data rate would have been selected.

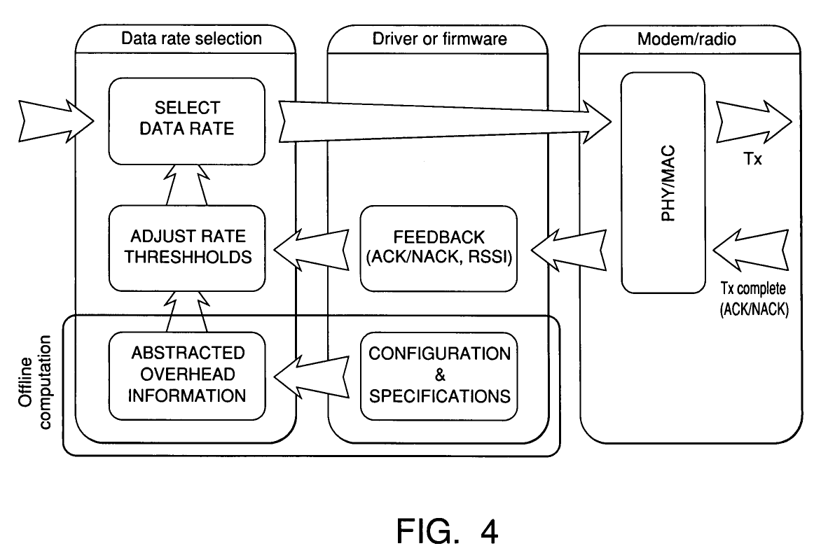

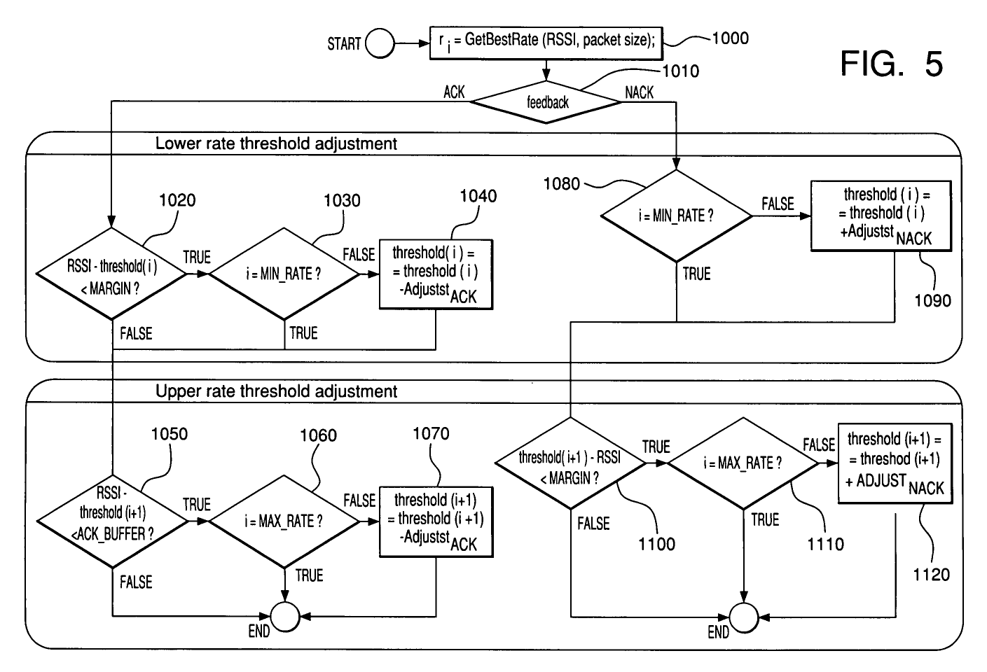

The present invention improves computational efficiency. FIG. 4 shows a block-diagram of the data rate selection process, which can be viewed in conjunction with FIG. 5. Most of the computationally-intensive calculations (i.e. determine the adjustment parameters by way of estimating the effective throughput) are performed offline, real-time computations are reduced to a minimum.

The present invention, in one embodiment, sets a series of target data packet completion rates and adjusts a set of data rate thresholds in such a way that the data rate selected provides the best estimated effective throughput.

The initial completion rate which all other completion rates derive from can be set by the system integrator at start-up. However, this completion rate can also be made to adapt to the environment. For example, if there are few neighbors, it might be beneficial to decrease the initial target completion rate and increase throughput (at the expense of packet retries). As the number of nodes in the neighborhood increases, the initial target completion could be set higher, thus ensuring that the wireless channel is better utilized by all the nodes.

Each data rate is associated with a particular threshold. An example is given in Table 1.

TABLE 1

| | | | | |
|---|---|---|---|---|
| Data Rate Index | 1 | 2 | 3 | 4 |
| Data Rate Value (Kbps) | 750 | 1500 | 3000 | 6000 |
| Data Rate Threshold (dBm) | −100 | −92 | −89 | −85 |

Each transmission is associated with a particular RSSI value: this is the predicted RSSI at the receiver's end: RSSI=Transmit_Power−Measured_{—Path}_Loss.

The data rate selection mechanism obeys the following three rules: (1) A data rate i can be selected if and only if RSSI>Threshold(i). (2) A data rate i cannot be selected if there exists a data rate j for which RSSI<Threshold(j) where j<i. In other words, for a specific RSSI value, the selected data rate is the highest data rate that does not violate any threshold restriction, knowing that a particular data rate cannot be allowed (regardless of whether it has a threshold restriction or not) if a lower data rate is disallowed. Example: if the data rate threshold array is {1: −100; 2: −80; 3: −70; 4: −72}, then the selected data rate for an RSSI of −71 dBm is “2”. In spite of the fact that “4” is an allowed data rate, “3” isn't. (3) The threshold for the lowest data rate cannot be modified and it is arbitrarily set to a value that is less than or equal to the lowest possible RSSI value of the system.

If the overall data packet completion rate falls below a certain threshold, all adjustment values for ACKs and NACKs may be modified to reflect the need for a faster convergence rate. Once the data packet completion rate returns is above a certain threshold, the adjustment values for ACKs and NACKs return to their original value to reflect the need for a more stable data rate selection.

The thresholds and adjustments can be averaged with a forgetting factor to converge to the initial values over time if, for example, the link is no longer used, since the node may have moved to another location.

One could forego rule (2) by ensuring that Threshold(i)<Threshold(i+1) for all i. This would require a computationally expensive iterative process, which is not conducive to an implementation in embedded systems. This is especially if there are a large number of data rates to choose from.

The mechanism for selecting the data rate is performed in the following order: when a packet needs to be sent, the transmit power is estimated. From this power estimation the RSSI is determined. From this RSSI value, the data rate is chosen by using the table of thresholds (Table 1). It should be noted that although the current data rate is chosen based on RSSI in this example, other parameters (such as Signal-to-Noise Ratio or Error Vector Magnitude) may be used instead.

After the packet/fragment has been sent, a transaction summary is reported to adjust the thresholds. The adjustments are performed according to the process given in FIG. 5. That is, the value for the best rate rᵢ is determined beginning at step 1000. At step 1010, it is determined whether an ACK (transmission success acknowledgment) or NACK (transmission failure acknowledgment) message was received by the node. For the purpose of link adaptation, not receiving an acknowledgment is identical to receiving a NACK message. If an ACK message was received, the process enters the lower rate threshold adjustment phase and continues to step 1020 to determine whether the value of “RSSI−threshold(i)” is less than the value MARGIN. If so, the processing proceeds to step 1030 where it is determined if the value of “i” (the data rate index) is not equal to the MIN_RATE. If the value of “i” is not equal to the MIN_RATE, the lower threshold value is adjusted in step 1040, and the processing proceeds to step 1050 to enter the upper rate threshold adjustment phase.

In step 1050, a decision is made whether the value of “RSSI−threshold(i+1)” is less than the value of ACK_BUFFER. If so, the processing proceeds to step 1060 where it is determined if the value of “i” is not equal to the MAX_RATE. If the value of “i” is not equal to the MAX_RATE, the upper threshold value is adjusted in step 1070, and the processing ends.

Looking back at the decision made in step 1010, if a NACK message was received, the process enters the lower rate threshold adjustment phase and continues to step 1080 to determine if the value of “i” is not equal to the MIN_RATE. If the value of “i” is not equal to the MIN_RATE, the lower threshold value is adjusted in step 1090, and the processing proceeds to step 1100, otherwise the processing proceeds directly to step 1100.

In step 1100, a decision is made whether the value of “RSSI−threshold(i+1)” is less than the value of MARGIN. If so, the processing proceeds to step 1110 where it is determined if the value of “i” is not equal to the MAX_RATE. If the value of “i” is not equal to the MAX_RATE, the threshold value is adjusted in step 1120, and the processing ends.

It is noted that the values for Adjust_{ACK} and Adjust_{NACK} reflect the target packet completion rate according to the following formulas:

$${Adjust}_{NACK} = {Adjust}_{ACK} \times ( \frac{Target PCR}{Target PCR - 1} )$$

$${Adjust}_{ACK} = {Adjust}_{NACK} \times ( \frac{1}{Target PCR} - 1 )$$

The integrator has the option of fixing one of Adjust_{AcK} or Adjust_{NACK} and computing the other. The selected value should be small enough to prevent large oscillations of data rates and large enough to converge quickly. In the exemplary embodiment Adjust_{AcK} is set at 0.025 dB.

The values for Adjust_{AcK} and Adjust_{NACK} allow for the threshold values to be adjusted in such a way that the upper data rate ends up being selected (after a certain number of iterations) if the actual packet completion rate is higher than the target packet completion rate; and the lower data rate ends up being selected (after a certain number of iterations) if the actual packet completion rate is lower than the target packet completion rate. In practice, the system will oscillate between two data rates, one for which the actual completion rate is higher than its target, and one for which the actual completion rate is lower than its target. One advantage of this method is the fact that the system does not directly need to compute the actual data packet completion rate, which is a computationally expensive procedure; it can add only Adjust_{AcK} and Adjust_{NACK} values to data rate thresholds—a computationally inexpensive procedure.

MARGIN (set in the exemplary embodiment at 2 dB) is a mechanism that ensures that higher data rates are not selected for larger packets sizes unless enough positive statistics have been collected. Also, it allows for faster convergence to higher or lower data rates when conditions change rapidly.

ACK_BUFFER (set in the exemplary embodiment at 1 dB) ensures that sporadic successes with higher data rates (by opposition to consistent ones) do not facilitate higher data rate selection unreasonably (this is particularly important with respect to power control or fast variations in signal strength).

At initialization, all adjustment parameters (per data rate, per packet/fragment sizes) are determined from an array provided by the system integrator. The attributes include data rate, sensitivity in dBm and overhead for different packet size quantizations and data rates.

The sensitivity information is used to initialize the threshold table. Optionally, the rate thresholds can be forced not to go below the sensitivity vales regardless of the success rate. The overhead information and data rate in Kbps is used to determine the ADJUST_ACK and ADJUST_NACK variables. The overhead information and data rate in Kbps is also used to determine a reference metric bias.

Higher data rates can be tried at different time intervals to take into account fading and collisions due to the high channel contention. For example, if the number of hidden nodes in a 802.11 network is high (e.g. a high value in the 802.11k hidden node measurement report) higher data rates may be tried to decrease the collision probability.

An example of a target packet completion rate computation is given below for a simplistic case where the number of retries is not limited by the MAC layer and the same data rate is used for each attempt.
l=packet length
r=data rate
PCR=packet completion rate
tₛ=duration of a successful packet transmission
tₑ=extra time required if the packet transmission fails (including estimated channel access delay)

$$\begin{matrix}Effective \\ Throughput\end{matrix} ( r , l ) = l \cdot \frac{PCR ( r , l )}{{t}_{s} ( r , l ) + ( 1 - PCR ( r , l ) ) \cdot {t}_{e}}$$

It should be noted that in the above equation, the penalty for retransmission may include the estimated extra delay for the next access attempt depending on the MAC characteristics. This may be estimated or measured neighborhood activity level for contention based systems (such as DCF in CSMA/CA systems) or estimated next reservation time for contention-free (reservation based) systems (such as TDMA based systems).

Another example of a target packet completion rate computation is given below for a simplistic case where the packet is fragmented and the number of retries is not limited by the MAC layer and the same data rate is used for each attempt.
l=packet length
l_{f}=fragment length
N=number of fragments
r=data rate
PCR=fragment completion rate
tₛ=duration of a successful packet transmission not including the durations of the fragments and their acknowledgments.
t_{fr}=duration of the fragments'transmission and the corresponding acknowledgments'reception.
tₑ=extra time required if the packet transmission fails (including estimated channel access delay)

$$\begin{matrix}Effective \\ Throughput\end{matrix} ( r , l ) = l \cdot \frac{PCR ( r , {l}_{f} )}{{Nt}_{fr} + ( N - ( N - 1 ) PCR ( r , {l}_{f} ) ) \cdot {t}_{s} + N ( 1 - PCR ( r , {l}_{f} ) ) {t}_{e}}$$

It should be noted that in the above equation, the penalty for retransmission may include the estimated extra delay for the next access attempt depending on the MAC characteristics. This may be estimated or measured neighborhood activity level for contention based systems (such as DCF in CSMA/CA systems) or estimated next reservation time for contention-free (reservation based) systems (such as TDMA based systems).

The target PCR values for every packet length range and data rate are then computed so that the effective throughput value for the higher data rates is equal to that of lowest data rate. The target PCR corresponds to the minimum required PCR, hence higher throughput values can be achieved if the actual PCR is higher than the target PCR. A limit on the minimum target PCR can be set depending on the tₑ values that depend on the MAC level overhead and channel access capabilities.

An example is given below for a MACA type system where the possible rates are 1.5, 3, 4 and 6 Mbps.

tₛ ,(lr) in microseconds is given in the following table. Note that the following values take into account the MAC overhead (including any fairness time):

TABLE 2

| | |
|---|---|
| Packet size | Data rate |

| (bytes) | 6 Mbps | 4 Mbps | 3 Mbps | 1.5 Mbps |
|---|---|---|---|---|
| 128 | 2373 | 2453 | 2668 | 3203 |
| 256 | 2628 | 2828 | 3123 | 4168 |
| 384 | 2828 | 3203 | 3578 | 5078 |
| 512 | 3123 | 3578 | 4168 | 6203 |
| 640 | 3378 | 3953 | 4623 | 7168 |
| 768 | 3578 | 4328 | 5078 | 8078 |
| 896 | 3873 | 4703 | 5668 | 9203 |
| 1024 | 4128 | 5078 | 6123 | 10168 |
| 1280 | 4623 | 5828 | 7168 | 12203 |
| 1408 | 4878 | 6203 | 7623 | 13168 |

t_ack_timeout=1500 μs;
ack_proc=225 μs;
tx_ack=148 μs;
tₑ =t_ack_timeout—ack_proc-tx_+t_backoff+MAC_penalty

First the effective throughput value for the lowest rate with an arbitrary target PCR for a specific strength is computed:

$$\begin{matrix}Effective \\ Throughput\end{matrix} ( {r}_{0} , l ) = l \cdot \frac{PCR ( {r}_{0} , l )}{{t}_{s} ( {r}_{0} , l ) + ( 1 - PCR ( {r}_{0} , l ) ) \cdot {t}_{e}}$$

Then the target PCR for every other rate is computed as:

$$PCR ( r , l ) = \begin{matrix}Effective \\ Throughput\end{matrix} ( {r}_{0} , l ) \cdot \frac{{t}_{s} ( r , l ) + {t}_{e}}{l + {t}_{e} \cdot \begin{matrix}Effective \\ Throughput\end{matrix} ( {r}_{0} , l )}$$

Note that tₑ can be dependent on the number of retransmission attempts as in the 802.11 type networks. However, the penalty term is dominant for this type of MAC protocols. Nevertheless, different formulas can be used for effective throughput computation. The following table displays the target PCR values (for every rate) which yields the same effective throughput as the lowest data rate with a target PCR equal to 1.

TABLE 3

| | Effective | Target | Target | Target |
|---|---|---|---|---|
| packet size | Throughput | PCR at | PCR at | PCR at |
| (bytes) | at 1.5 Mbps | 3 Mbps | 4 Mbps | 6 Mbps |
| 128 | 0.3197 | 0.99243 | 0.98939 | 0.98826 |
| 256 | 0.49136 | 0.98541 | 0.98129 | 0.9785 |
| 384 | 0.60496 | 0.97932 | 0.97415 | 0.96899 |
| 512 | 0.66033 | 0.97238 | 0.96437 | 0.95819 |
| 640 | 0.71429 | 0.9659 | 0.95692 | 0.94922 |
| 768 | 0.76058 | 0.96029 | 0.95036 | 0.94043 |
| 896 | 0.77888 | 0.95389 | 0.94131 | 0.93048 |
| 1024 | 0.80566 | 0.9479 | 0.93444 | 0.9222 |
| 1280 | 0.83914 | 0.9368 | 0.91998 | 0.90486 |
| 1408 | 0.85541 | 0.93124 | 0.91363 | 0.89719 |

The following table displays the margin for throughput improvement when transmissions with different data rates yield higher PCR than their target PCR values:

TABLE 4

| | Maximum | Maximum | Maximum | Maximum |
|---|---|---|---|---|
| | effective | effective | effective | effective |
| packet | throughput | throughput | throughput | throughput |
| size | at 1.5 Mbps | at 3 Mbps | at 4 Mbps | at 6 Mbps |
| (bytes) | (Mbps) | (Mbps) | (Mbps) | (Mbps) |
| 128 | 0.3197 | 0.38381 | 0.41745 | 0.43152 |
| 256 | 0.49136 | 0.65578 | 0.72419 | 0.7793 |
| 384 | 0.60496 | 0.85858 | 0.9591 | 1.0863 |
| 512 | 0.66033 | 0.98273 | 1.1448 | 1.3116 |
| 640 | 0.71429 | 1.1075 | 1.2952 | 1.5157 |
| 768 | 0.76058 | 1.2099 | 1.4196 | 1.7172 |
| 896 | 0.77888 | 1.2646 | 1.5241 | 1.8508 |
| 1024 | 0.80566 | 1.3379 | 1.6132 | 1.9845 |
| 1280 | 0.83914 | 1.4286 | 1.757 | 2.215 |
| 1408 | 0.85541 | 1.4776 | 1.8159 | 2.3091 |

An aspect of the present invention is the selection of a multicast data rate. The data rate adaptation algorithm described above can be also applied for reliable multicasting. One way to achieve this is to select initially a node with the minimum link quality to send acknowledgments and adjust the data rate to support the link with the minimum link quality for a given QoS level. Other nodes can be visited to update the worst link. Another way is to allow receiver based link quality measurements to be distributed to the sender. For MACA type systems where the RTS is sent before the data, the receiver can update its data receive timeout statistics (or sequence number of data if available) to update the link quality metric and inform the sender when link quality drops to some predetermined threshold.

Another aspect of the present invention is the selection of an optimal rate in congested networks where multiple nodes have to compete for the resources of the same node. The MAC penalty in tₑ may be computed in different ways by considering the tradeoff between complexity and accuracy. An average value from previous statistics may be used for minimal complexity. The node can measure the delay between retransmission attempts of the same packet or fragment for a more accurate estimation. The node can also estimate the average waiting time by estimating the neighborhood activity. For example, in 802.11 networks, this may be achieved by using the measurement actions introduced in 802.11h and being extended in 802.11k, such as channel load at the transmitter and the receiver sites. For TDMA systems, the schedule for slot allocations can be used to update the waiting time between retransmissions. The effective throughput computation also includes QoS levels of the packet. For example, the channel access times (such as interframe space and backoff window parameters in 802.11e and slot allocations in TDMA systems) are different for packets with different priority levels. Therefore, the expected delay will be smaller for higher priority packets while target packet completion rates may be higher.

Although only a few exemplary embodiments of the present invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

1. A method for selecting a data rate by a node in a wireless communication network, the method comprising:
predicting a traffic throughput at the node for each of a plurality of potential data rates;
converting each of the predicted traffic throughputs into a respective target packet completion rate for each of a respective potential data rate; and
selecting the data rate based on an assessment of the actual packet completion rate in comparison with the respective target packet completion rates.

2. A method as claimed in claim 1, wherein:
the predicting step comprises predicting the traffic throughput for said each potential data rate based on at least one condition at the physical layer.

3. A method as claimed in claim 2, wherein the at least one condition comprises at least one of the following:
expected packet completion rate at each said data rate;
transmission time of each data rate, including overhead and variations due to packet length;
time lost due to failed packet transmissions at each said data rate; and
queuing delays at each said data rate.

4. A method as claimed in claim 1, wherein the converting step determines the respective target packet completion rate that maximizes the throughput at its corresponding respective potential data rate.

5. A method as claimed in claim 4, wherein the target packet completion rate is calculated according to the following equation:
$$PCR ( r , l ) = \begin{matrix}Effective \\ Throughput\end{matrix} ( {r}_{0} , l ) \cdot \frac{{t}_{s} ( r , l ) + {t}_{e}}{l + {t}_{e} \cdot \begin{matrix}Effective \\ Throughput\end{matrix} ( {r}_{0} , l )}$$
where:
Effective Throughput (ET) (r₀, l)=the predicted traffic throughput for a particular data rate and packet length;
l=packet length;
r=data rate;
r₀ =reference data rate used to determine the predicted effective throughput;
PCR=packet completion rate;
tₛ=duration of a successful packet transmission; and
tₑ=extra time required if the packet transmission fails, including estimated channel access delay.

6. A method as claimed in claim 1, wherein the selecting step comprises adjusting the respective data rate threshold values.

7. A method as claimed in claim 6, wherein said adjusting data rate threshold values is performed according to the following equations:
$${Adjust}_{NACK} = {Adjust}_{ACK} \times ( \frac{Target PCR}{Target PCR - 1} )$$
$${Adjust}_{ACK} = {Adjust}_{NACK} \times ( \frac{1}{Target PCR} - 1 )$$
where Target PCR represents a target packet completion rate, Adjust_{AcK} represents an adjustment applied to the data rate thresholds when the node successfully transmits a packet at a selected data rate and Adjust_{NACK} represents an adjustment applied to the data rate thresholds when the node fails to transmit a packet at a selected data rate.

8. A method as claimed in claim 6, wherein said adjusting the data rate threshold values comprises increasing the selected data rate when the actual packet completion rate is higher than the target packet completion rate, and wherein said adjusting the data rate threshold values comprises decreasing the selected data rate when the actual packet completion rate is lower than the target packet completion rate.

9. A method as claimed in claim 6, wherein the selecting step further comprises selecting the data rate by comparing a current condition at the physical layer to the data rate threshold values.

10. A method as claimed in claim 9, wherein the current condition at the physical layer comprises at least one of the received signal strength, the signal-to-noise ratio, and the error vector magnitude.

11. A node, adapted for communication in a wireless communication network, and capable of adjusting its rate of communication, the node comprising:
a controller, adapted to predict traffic throughput at the node for each of a plurality of potential data rates, convert each of the predicted traffic throughput into a respective target packet completion rate for each of a respective potential data rate, and select the data rate based on an assessment of the actual packet completion rate in comparison with the respective target packet completion rates.

12. A node as claimed in claim 1, wherein:
the controller is adapted to predict the traffic throughput for said each potential data rate based on at least one condition at the physical layer.

13. A node as claimed in claim 12, wherein the at least one condition comprises at least one of the following:
expected packet completion rate at each said data rate;
transmission time of each data rate, including overhead and variations due to packet length;
time lost due to failed packet transmissions at each said data rate; and
queuing delays at each said data rate.

14. A node as claimed in claim 11, wherein the converting determines the respective target packet completion rate that maximizes the throughput at its corresponding respective potential data rate.

15. A node as claimed in claim 14, wherein the target packet completion rate is calculated according to the following equation:
$$PCR ( r , l ) = ET ( {r}_{0} , l ) \cdot \frac{{t}_{s} ( r , l ) + {t}_{e}}{l + {t}_{e} \cdot ET ( {r}_{0} , l )}$$
where:
Effective Throughput (ET) (r₀, l)=the predicted traffic throughput for a particular data rate;
l=packet length;
r=data rate;
PCR=packet completion rate;
tₛ=duration of a successful packet transmission; and
tₑ=extra time required if the packet transmission fails, including estimated channel access delay.

16. A node as claimed in claim 11, wherein the selecting step comprises adjusting the respective data rate threshold values.

17. A node as claimed in claim 16, wherein said adjusting data rate threshold values is performed according to the following equations:
$${Adjust}_{NACK} = {Adjust}_{ACK} \times ( \frac{Target PCR}{Target PCR - 1} )$$
$${Adjust}_{ACK} = {Adjust}_{NACK} \times ( \frac{1}{Target PCR} - 1 )$$
where Target PCR represents a target packet completion rate, Adjust_{AcK} represents an adjustment factor applied to the data rate thresholds when the node successfully transmits a packet at a selected data rate and Adjust_{NACK} represents an adjustment applied to the data rate thresholds when the node fails to transmit a packet at a selected data rate.

18. A node as claimed in claim 16, wherein said adjusting the data rate threshold values comprises increasing the selected data rate when the actual packet completion rate is higher than the target packet completion rate, and wherein said adjusting the data rate threshold values comprises decreasing the selected data rate when the actual packet completion rate is lower than the target packet completion rate.

19. A node as claimed in claim 16, wherein:
the controller is adapted to select the data rate by comparing a current condition at the physical layer to the data rate threshold values.

20. A node as claimed in claim 19, wherein the current condition at the physical layer comprises at least one of the received signal strength, the signal-to-noise ratio, and the error vector magnitude.
